(19) United States
(12) Patent Application Publication
(10) Pub. No.: US 2021/0167580 A1
(43) Pub. Date: Jun. 3, 2021

(54) TOP EMITTING VCSEL ARRAY WITH INTEGRATED GRATINGS

(71) Applicant: PINNACLE PHOTONICS (US), INC., Berkeley, CA (US)

(72) Inventors: Pengfei Qiao, Albany, CA (US); Jonas Kapraun, Albany, CA (US)

(73) Assignee: PINNACLE PHOTONICS (US), INC., Berkeley, CA (US)

(21) Appl. No.: 16/818,700

(22) Filed: Mar. 13, 2020

Related U.S. Application Data
(60) Provisional application No. 62/942,065, filed on Nov. 29, 2019.

(51) Int. Cl. H01S 5/183; H01S 5/042; H01S 5/42

(52) U.S. Cl. CPC H01S 5/18386; H01S 5/34; H01S 5/423; H01S 5/04256

(57) ABSTRACT

Top emitting vertical cavity surface emitting lasers (VCSELs) are described with various top side optical gratings, etched into and/or fabricated over the VCSELs, to configure optical emission properties to suite a wide range of applications. Top side gratings are configured for spanning one or multiple emitters in any desired alignment/misalignment, using a wide range of refractive index materials and arrangements, levels of dimensionality (1D, 2D or 3D), forms of chirping of the grating, various grating periods, transmissive/reflective properties and in-plane coupling, ranges of diffractive orders, different relative amplitudes of transmitted and reflected orders, different polarizations, different levels of collimation, different levels of divergence, different diffraction and reflection, different beam diffusion, fixed or varied rotation of optical output, and far field engineering of the optical output.

### CROSS-REFERENCE TO RELATED APPLICATIONS

This application claims priority to, and the benefit of, U.S. provisional patent application Ser. No. 62/942,065 filed on Nov. 29, 2019, incorporated herein by reference in its entirety.

### STATEMENT REGARDING FEDERALLY SPONSORED RESEARCH OR DEVELOPMENT

Not Applicable

### INCORPORATION-BY-REFERENCE OF COMPUTER PROGRAM APPENDIX

Not Applicable

### NOTICE OF MATERIAL SUBJECT TO

### COPYRIGHT PROTECTION

A portion of the material in this patent document may be subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND

### 1. Technical Field

The technology of this disclosure pertains generally to vertical cavity surface emitting lasers, and more particularly to gratings integrated into top emitting VCSEL structures.

### 2. Background Discussion

Vertical cavity surface emitting lasers (VCSELs) have provided many advantages as light sources for optical sensing and communication. Such advantages include low cost, wafer-level testing and screening, good beam quality, possibility for large or dense arrays, and so on. However, present VCSELs are often difficult to integrate into system level circuits.

Accordingly, a need exists for a VCSEL structures with enhanced optical properties to suit a range of applications. The present disclosure fulfills that need and provides additional benefits over previous technologies.

### BRIEF SUMMARY

This disclosure describes, in one embodiment, an array of top emitting VCSELs with integrated, engineered gratings on the emitting surface. Integration of optically active structures on the top side of a top emitting VCSEL array enables functionalities, such as diffusion, beam replication, focusing, collimation, polarization and other functionalities conventionally achieved by adding additional optical components external of the device. An engineered grating can be used to optically couple a group of emitters. Combinations of the above-mentioned functionalities can be achieved as well. In a VCSEL array with different electrically separated emitter zones beam steering can be achieved.

VCSEL arrays with polarized emissions offer improved optical stability and sensing signal-to-noise ratio. Using conventional methods such as engineering oxide apertures, cavity shapes, current injection profiles makes it very challenging to obtain high polarization selectivity (typically greater than 20 dB is required).

In various embodiments, this disclosure describes VCSELs with engineered top gratings that can be either be sub-wavelength (period less than the wavelength) or diffractive (period greater than or equal to the wavelength), with periodicity in 1D, 2D or 3D, and with shapes being regular, chirped or irregular. Gratings can also be quasi-periodic or aperiodic.

In various embodiments, the gratings may act (1) as optical element(s) shaping the characteristics of the emitted far field of the array, (2) as polarization, angle, mode or wavelength selective mirror of the cavity, (3) as optical coupler between multiple elements of the array or (4) as any combination of the above mentioned functionalities.

In various embodiments, diffraction phase gratings, high contrast gratings, and other engineered gratings can be implemented on the VCSEL top side with simplicity in design and fabrication.

In various embodiments, a top emitting VCSEL array with integrated engineered gratings on the top can have a designed far-field intensity and polarization distribution.

In various embodiments, beam steering and polarization switching can be achieved when parts of the array can be electrically addressed separately, or in groups within the array.

It should be appreciated that in these embodiments, the grating integrated over the VCSEL structure is not to be confused with the upper reflector of the VCSEL, which already bounds the upper optical cavity, but is instead an additional grating over the emission area of the VCSEL, or array of VCSELs, and is configured to perform other functionalities.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWING(S)

The technology described herein will be more fully understood by reference to the following drawings which are for illustrative purposes only:

FIG. 1 is a cross-section view of a top-emitting oxide-confined VCSEL having a high contrast grating integrated over the top side surface of said VCSEL according to at least one embodiment of the present disclosure.

FIG. 2A through FIG. 2D are cross-section views of configuring a VCSEL, or VCSEL array, with a top side grating structure according to at least one embodiment of the present disclosure.

FIG. 3A and FIG. 3B are cross-section views of different structures in which a grating is formed into the top surface of a VCSEL, or VCSEL array, according to at least one embodiment of the present disclosure.

FIG. 4A through FIG. 4D are cross-section views of the top side of a VCSEL, or VCSEL array, configured with different forms of optical gratings according to at least one embodiment of the present disclosure.

FIG. 5A through FIG. 5C are isometric views of gratings configured with different dimensionality that can be formed on the top side of a VCSEL, or VCSEL array, according to at least one embodiment of the present disclosure.

FIG. 6A through FIG. 6D are isometric views of gratings configured with different forms of chirping that can be formed on the top side of a VCSEL, or VCSEL array, according to at least one embodiment of the present disclosure.

FIG. 7A through FIG. 7D are cross-section views of the top side of a VCSEL configured with different grating periods according to at least one embodiment of the present disclosure.

FIG. 8A through 8D are cross-section views of the top side of a VCSEL, or VCSEL array, configured for changing relative amplitudes of transmitted and reflected orders according to at least one embodiment of the present disclosure.

FIG. 9A through 9C are cross-section views of the top side of a VCSEL, or VCSEL array, configured with gratings that provide different functionalities, including lateral optical coupling, according to at least one embodiment of the present disclosure.

FIG. 10A through FIG. 10F are cross-section views of the top side of a VCSEL, or VCSEL array, configured with gratings to provide far field control and showing their different output patterns according to at least one embodiment of the present disclosure.

FIG. 11A and FIG. 11B are cross-section views of the top side of a VCSEL, or VCSEL array, having a grating or gratings configured to operate as a lens or lenses according to at least one embodiment of the present disclosure.

FIG. 12A through FIG. 12D are cross-section views of the top side of a VCSEL, or VCSEL array, configured for different polarized emissions and their associated emission patterns according to at least one embodiment of the present disclosure.

FIG. 13A and FIG. 13B image renditions depicting a far field output from a VCSEL, or VCSEL array, configured with a polarizer and diffuser according to at least one embodiment of the present disclosure.

FIG. 14A through FIG. 14C image renditions depicting a far field output from a VCSEL, or VCSEL array, configured with a top surface with a structured far field grating according to at least one embodiment of the present disclosure.

### DETAILED DESCRIPTION

1. Integration of Gratings on VCSELs

The ability to engineer the emissive optical properties of a VCSEL, or VCSEL array, is critical for VCSEL design in numerous applications, such as in 3D sensing applications. Typically, additional optical components (e.g., lenses, diffusers, diffractive optical elements) must be integrated at the package-level for collimating, diffusing or replicating the VCSEL beam. Monolithically integrated optical components can provide significant cost savings and package size reductions.

VCSELs, such as 3D sensing VCSELs, have a high efficiency requirement for power consumption with the top DBR being a bottleneck for efficiency improvements in conventional VCSELs. Partially or fully replacing the top DBR by integrated gratings can significantly reduce the voltage drop and power consumption on the top mirror, while maintaining high mirror reflectivity and low VCSEL threshold.

In order to make VCSEL array emissions suitable for 3D sensing schemes such as time-of-flight (TOF) or structured light (SL), one or more layers of optical components such as a diffractive optical element (DOE) or diffuser are typically required in the sensing module. These components significantly increase module size, assembly complexity and cost.

Currently VCSEL arrays and optical components are designed and fabricated separately. The mismatch between them induces loss of efficiency and degradation of optical functionalities.

1.1. Top Emitting VCSEL with Top Side HCG

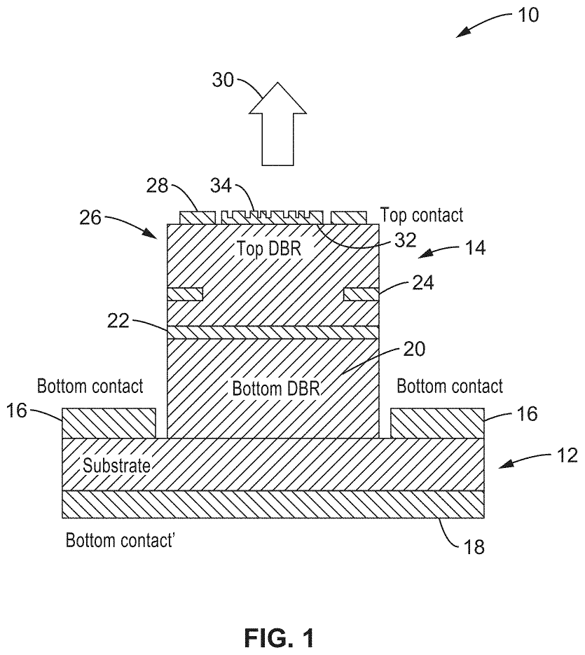

FIG. 1 illustrates a schematic 10 for a top emitting oxide-confined VCSEL with a top side grating. The device is exemplified having a substrate portion 12 and a cavity portion 14. The n-contact, also referred to as the bottom contact, is formed either above or below substrate 12. In a first case a contact 16 is deposited on the etched parts over the top side (e.g., near the bottom DBR) on a specially n-doped contact layer or on the substrate surrounding the cavity structure. In a second case contact 18 is formed on the bottom side of substrate 12 as a bottom contact. Cavity portion 14 of the VCSEL is depicted herein with a bottom DBR 20, over which is a quantum well structure (active region) 22, above which is an aperture 24, over which is a top reflector shown as DBR 26, depicted here with emitting surface 32, which is planar, and on a periphery over the top of cavity portion 14 upon which is deposited a top contact 28.

It should be appreciated that the upper reflector may comprise either a DBR, or an HCG layer which can be used partially or fully in place of the DBR. Such HCG layer can either be beneath a low index material whose surface has been planarized, or be extruding from the top surface.

A high contrast grating 34 is integrated over the top side surface 32 of said VCSEL as a top side high contrast grating which is configured as an optically active structure for modifying emissions of one VCSEL, or multiple VCSELs within an array of VCSELs, to enable optical functionalities. It should be appreciated that grating 34 may comprise any of the grating embodiments described herein or combinations thereof. The direction of laser emission output is depicted by arrow 30. It will be appreciated that top contact 28 can be formed on the topside side of the VCSEL structure on the non-emission area of the VCSEL, or as a transparent contact formed on the patterned emission area.

The above description is given by way of example as VCSELs can be fabricated with numerous variations regarding the specific layers and their materials. However, the present disclosure can be implemented on VCSELs having a wide range of internal structures because the present disclosure is primarily directed at configuring the top surface of these VCSEL devices, or VCSEL arrays.

In the present disclosure, a number of embodiments are described for different structures and manufacturing for the top portion of cavity structure 14. For example instead of emitting on the top side of the substrate of the device through a planar surface as shown, one can configure the device with a grating layer at the top emitting interface of a single VCSEL or over a plurality of VCELSs in a VCSEL array. In addition, the contact 28 depicted in FIG. 1 as formed on the top side of the VCSEL structure can be formed on either the area patterned with the engineered grating, or on an area that is not patterned with the engineered grating. Furthermore, the contact on the topside side of the VCSEL structure can be formed over of any number of layers deposited to form the engineered grating, or this contact may be formed on an area where the aforementioned layers are not present, and thus formed directly on top of the VCSEL structure.

It should be appreciated that the above VCSEL structure is shown by way of example and not limitation, and that the following VCSEL top surface fabrication methods and structures are applicable to a wide range of VCSEL structures having a top surface through which light is emitted. Alternatively, these grating structures can be implemented on either the top or the bottom surfaces of either top or bottom emitting VCSELs, or any combination of the above.

1.2. Top Emitting VCSEL Array with Top Side HCG

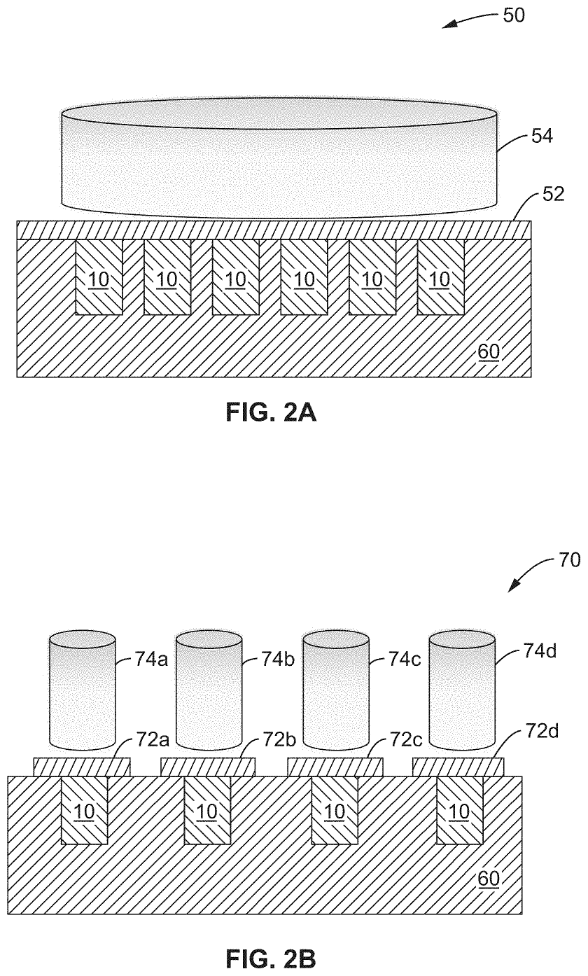

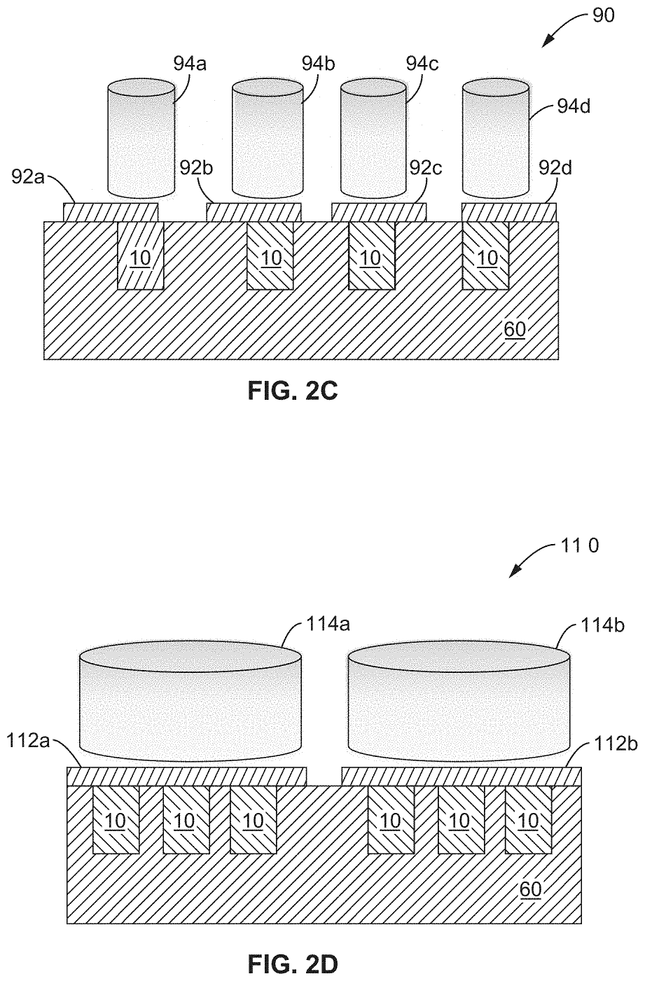

FIG. 2A through FIG. 2D illustrate example embodiments 50, 70, 90 and 110, showing different configurations of topside gratings utilized for VCSELs 10 within a planarized optical substrate or carrier submount 60, and with respect to either individual VCSEL emitters, or spanning multiple emitters of an array of VCSELs.

FIG. 2A illustrates an example embodiment 50 in which the top side grating 52 spans the entire emission area of the VCSEL array of individual VCSELs 10, with the array shown emitting a combined light pattern 54.

FIG. 2B illustrates an example embodiment 70 in which a topside grating 72a, 72b, 72c, 72d is aligned with each VCSEL emitter 10 of the VCSEL array, and depicting separate optical emissions 74a, 74b, 74c and 74d.

FIG. 2C illustrates an example embodiment 90 in which the topside gratings 92a, 92b, 92c and 92d are configured for being intentionally misaligned with VCSEL emitters 10, to generate optical emissions 94a, 94b, 94c and 94d. Such designed or random misalignment can produce engineered beam shapes equivalent to passing through diffusion or refraction or diffraction optical elements.

FIG. 2D illustrates an example embodiment 110 in which the topside gratings 112a, 112b are configured to cover different sections of the array of VCSELs 10 (different groups of VCSELs within the array), for a combined light output 114a, 114b in each section. In at least one embodiment, the sections of the VCSEL array are configured for being electrically addressed separately. The present disclosure describes embodiments in which each VCSEL in the array can be electrically addressed either collectively in groups or across the whole array, or each VCSEL may be electrically addressed separately. Thus, it should be appreciated that VCSELs as described throughout the present disclosure may be addressed separately, or in groups, or collectively.

2. Gratings Materials and Structural Designs

2.1. Grating Formation and Materials.

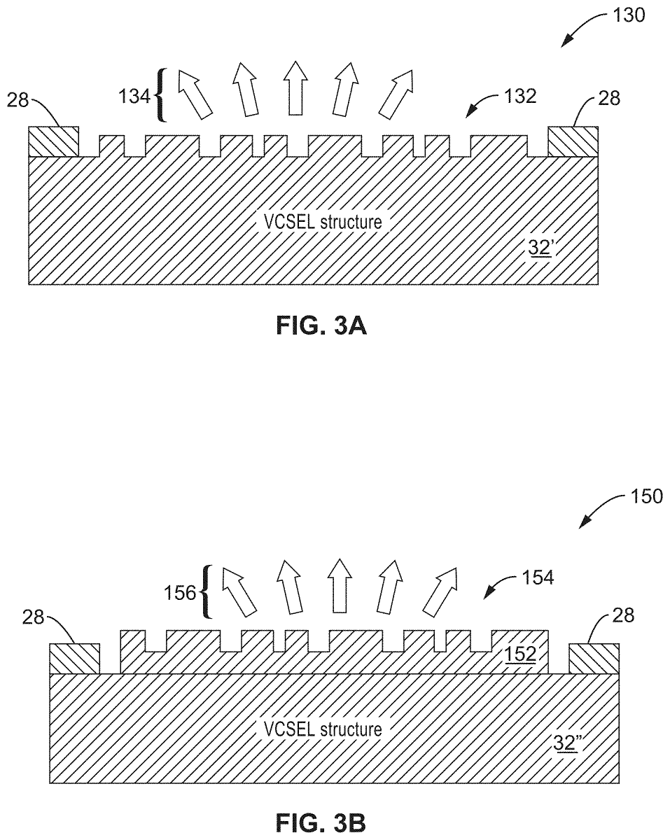

FIG. 3A and FIG. 3B illustrate example embodiments 130, 150 for fabricating a high contrast grating (HCG) at the top interface (surface) of a VCSEL, or VCSEL array. The arrows indicate emission through the top side of the device. The light transmitted and reflected by the grating pattern is split in diffraction orders. These orders may or may not be spatially or angularly distinct, depending on the input beam and the design.

FIG. 3A shows a VCSEL 130 in which a grating 132 has been etched into upper surface 32′ of the VCSEL and depicts optical output 134. A top contact 28 is shown by way of reference. FIG. 3B shows a VCSEL 150 having top interface 32″ over which an additional layer 152 is deposited and patterned into an optical grating 154 and depicts optical output 156. A top contact 28 is shown by way of reference. It will be appreciated that gratings for the above examples and others described in the present disclosure can be selected from group of materials consisting essentially of GaAs, AlGaAs, SiNx, SiO₂, Al₂O₃, InGaP, or other suitable materials and combinations thereof.

2.2. HCG and High Contrast Metastructure (HCM).

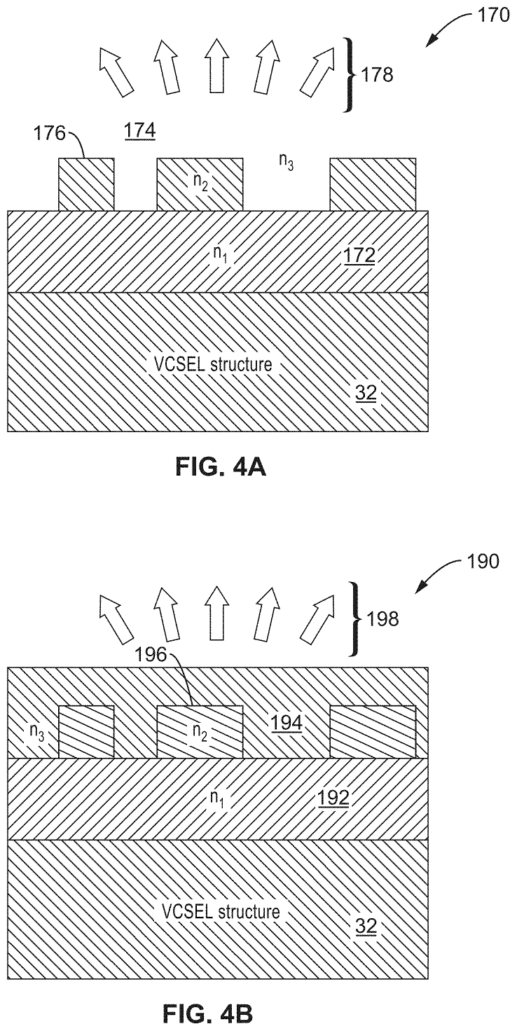

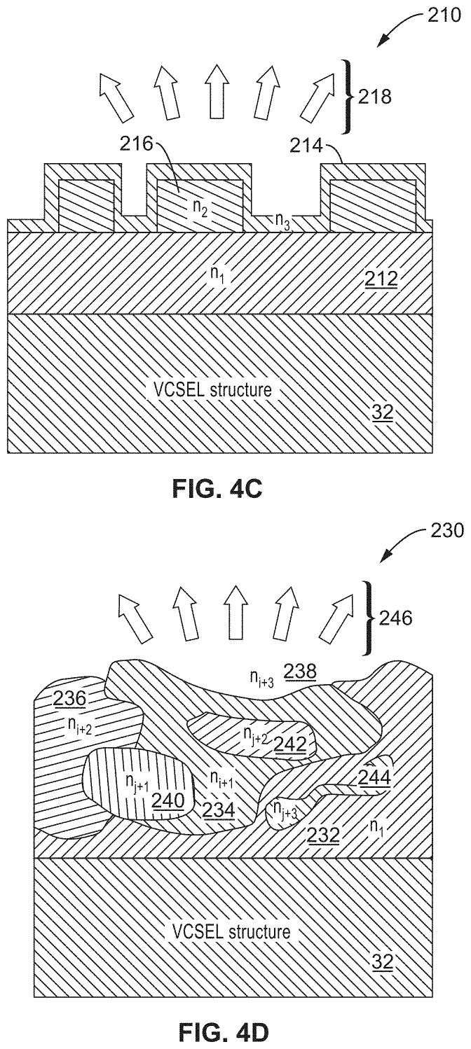

FIG. 4A through FIG. 4D illustrate example embodiments 170, 190, 210, 230 showing different forms of gratings which may be formed at the top interface 32 of a VCSEL. It should be appreciated that the present disclosure also contemplates, without limitation, both intra-figure and inter-figure combinations of the apparatus and methods described for these figures.

FIG. 4A exemplifies a grating formed with a high index grating layer n2 176 on top of a low index layer n1 172 and interfacing the free space low index area n3 174, with optical output 178.

FIG. 4B exemplifies a VCSEL structure having a top side high index grating n2 196, over a low index n1 layer 192 and covered by a planar low index material n3 194, with optical output 198 shown.

FIG. 4C exemplifies a VCSEL structure having low index n1 layer 212 over which is a high index n2 grating 216 and which is conformally covered by a low index later n3 214.

FIG. 4D exemplifies a generalized schematic showing a grating configured having areas of materials with high optical refractive index nⱼ 240, 242 and 244, interfacing other areas of materials with low optical refractive index nᵢ 232, 234, 236 ad 238 so that regions of either group of materials surround regions of the other group of materials. An optical output 246 is seen in the figure. In this over the top VCSEL grating structure it will be appreciated that the number of refractive index materials utilized and the shapes and relationships to one another can be in any desired relationship in order to create a desired operation for the gratings. In this context the HCGs can also be generally referred to as high contrast metastructures (HCMs), due to the inclusion of aperiodic arrangement and irregular shapes. It should be appreciated that the refractive indices n1, n2 and n3 can theoretically be any values, while more preferably the values of n1, n2 and n3 are more typically among 1.5 (SiO₂), 1.8 (Al₂O₃), 2.0 (SiNx), 2.9 (AlAs), 3.2 (AlGaAs or InGaP), 3.5 (GaAs) or in a similar range. Example thickness of material 1 is about 0.1 λ₀ to 0.2 λ₀ (λ₀ is the operation wavelength). Example thickness of material 2 is about 0.14 λ₀ to 0.18 λ₀ or about 0.26 λ₀ to 0.30 λ₀. Example thickness of material 3 is about 0.05 λ₀ to 2 λ₀.

It should be appreciated that these top side grating compositions for the VCSEL, or VCSEL array, can be combined with other VCSEL grating configurations described in the present disclosure without limitation.

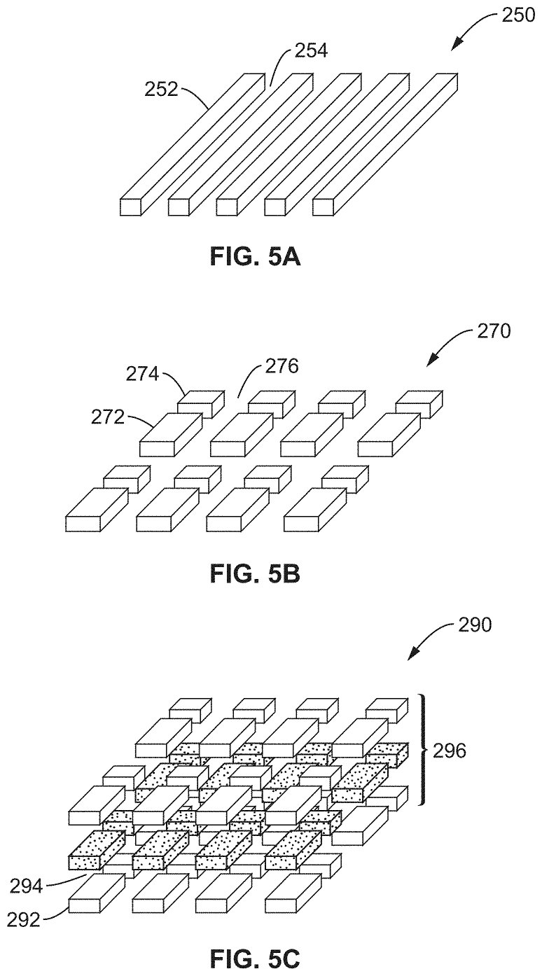

FIG. 5A through FIG. 5C illustrates example embodiments 250, 270 and 290 in which the grating may be realized with different levels of dimensionality engineered toward different objects. The top surface of the VCSEL can be configured with a one dimensional (1D) grating, a two dimensional (2D) grating, or a three dimensional (3D) grating.

FIG. 5A shows a 1D grating 250 having grating bars 252 and gaps 254. FIG. 5B shows a 2D grating 270 depicting islands 272a, 272b in void areas 276. It should be appreciated that there may be any desired number of island sizes. FIG. 5C shows a 3D grating 290, shown in an equivalent island 292 and void manner 294 as was seen in FIG. 5B, but in this three dimensional stack of layers 296.

It should be appreciated that these dimensionality changes described herein can be combined with other VCSEL grating configurations described in the present disclosure without limitation.

2.3. Chirped Gratings

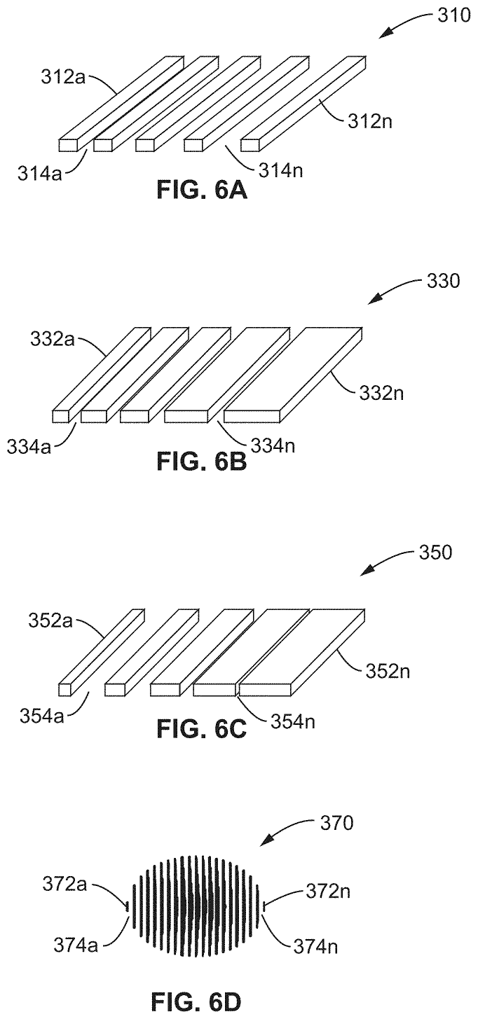

FIG. 6A through FIG. 6D illustrate example embodiments 310, 330, 350 and 370 of VCSEL top side chirped gratings. It will be noted that the term “chirped”, as utilized herein, denotes gratings which are configured with variable periods along the span of bars, or along/between the length of the bars. FIG. 6A depicts a grating 310 having a chirped period between 314a to 314n, and constant bar widths 312a to 312n. FIG. 6B depicts a grating 330 with a chirped bar width 332a to 332n, while the period between bars 334a to 334n is kept constant. FIG. 6C shows a grating 350 configured with both varying period 354a to 354n and varying bar width 352a to 352n. FIG. 6D shows a radially chirped grating 370 that may be used as a lens. The grating is shown with bars 372a through 372n, and gap width 374a through 374n, both of which vary. It will be noted that a periodic grating can be chirped in period, in bar width, in gap width, in duty cycle, in thickness or in any combination of those parameters. The chirp might be present along one or multiple directions and may vary spatially, too. Example bar width ranges are about 0.16 λ₀ to about 0.5 λ₀ (λ0 is the operation wavelength). Example air gap width ranges are about 0.1 λ₀ to about 0.6 λ₀ in which λ₀ is the operating wavelength.

It should be appreciated that the structures of these top side chirped gratings can be combined with other VCSEL grating configurations described in the present disclosure without limitation.

2.4. Significance of Grating Period

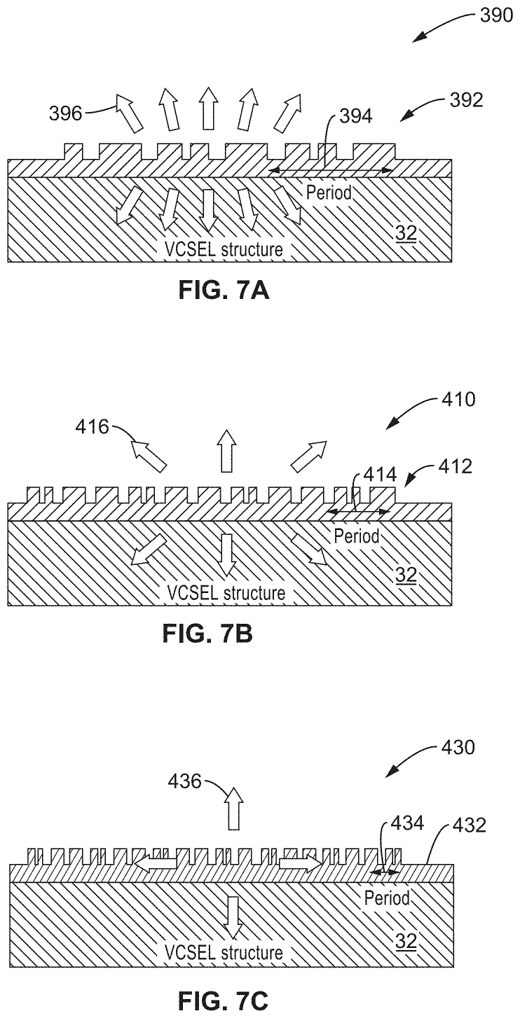

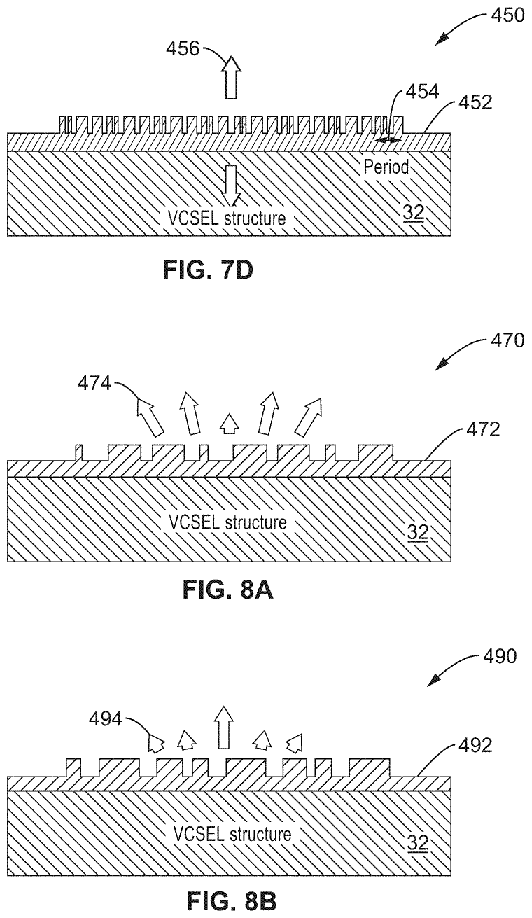

FIG. 7A through FIG. 7D illustrate example embodiments 390, 410, 430 and 450 in which different grating periods determine the angle of separation of the reflective and transmissive orders. FIG. 7A shows a diffractive VCSEL grating 392 having period 394, and shown with optical output 396 having many diffraction orders. In contrast to this FIG. 7B depicts a diffractive grating 412 having a period 414 and an optical output 416 having few diffraction orders. FIG. 7C shows a grating 432 having a period 434 and showing an optical output 436 that provides in-plane coupling via the 1st and −1st orders. FIG. 7D shows a sub-wavelength grating 452 with period 454, showing an optical output 456 that supports only fundamental orders. By choosing the grating period, there can be one or multiple diffraction orders emitted from the top emission area of the laser and reflected back into the VCSEL structure. The diffraction angles are determined by the period of the grating, with larger (smaller) periods providing smaller (larger) separation angles. At a specific period, the grating may act as an optical coupler between multiple elements of an array of VCSELs, such as seen in FIG. 7C. At periods smaller than the wavelength of the light the grating only supports fundamental modes. Example periods for subwavelength gratings is about 0.44 λ₀ to 0.47 λ₀ or 0.69 λ₀ to 0.75 λ₀ (λ0 is the operation wavelength). Example period for diffractive gratings is about 10 λ₀ to 20 λ₀.

It should be appreciated that the structures of these top side gratings with selective grating period can be combined with other VCSEL grating configurations described in the present disclosure without limitation.

2.5. Engineered Grating Design

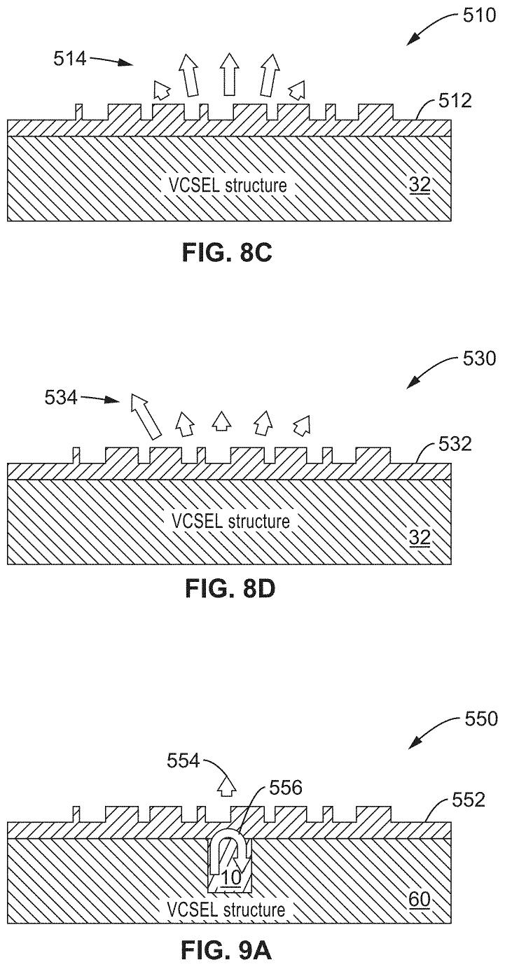

FIG. 8A through FIG. 8D illustrate example embodiments 470, 490, 510 and 530 in which the VCSEL, or VCSEL array, grating is configured to provide different relative amplitudes of the transmitted and reflected orders. In FIG. 8A the grating 472 of the VCSEL, or VCSEL array, is configured for suppressing the fundamental order of transmission as seen in the optical output 474. In FIG. 8B a grating 492 is shown for enhancing the fundamental order of transmission as seen optical output 494. FIG. 8C shows a grating 512 of the VCSEL, or VCSEL array, that is configured for supporting a number of orders, such as having equal amplitude, as indicated by the optical output 514. FIG. 8D shows a grating 532 of the VCSEL, or VCSEL array, that is configured for enhancing a number of orders and at the same time suppressing another number of orders, as seen in the optical output 534. In general, a number of orders can be engineered to have defined relative amplitudes.

By designing the structure within each period, the amplitudes of all diffraction orders can be configured to the desired application. In some cases, the fundamental order is enhanced (suppressed) relative to the other orders. In other cases, a number of orders are configured to have similar amplitudes, or a number of orders are enhanced while at the same time another number of orders are suppressed. In general, a number of orders can be configured to have defined relative amplitudes. It should be appreciated that the number of diffraction orders can range from approximately 3 to approximately 21.

It should be appreciated that the structures of these top side gratings with selective relative amplitudes of the transmitted and reflected orders can be combined with other VCSEL grating configurations described in the present disclosure without limitation.

3. Grating VCSEL Functionalities

3.1. Grating-Assisted Coupling and Feedback

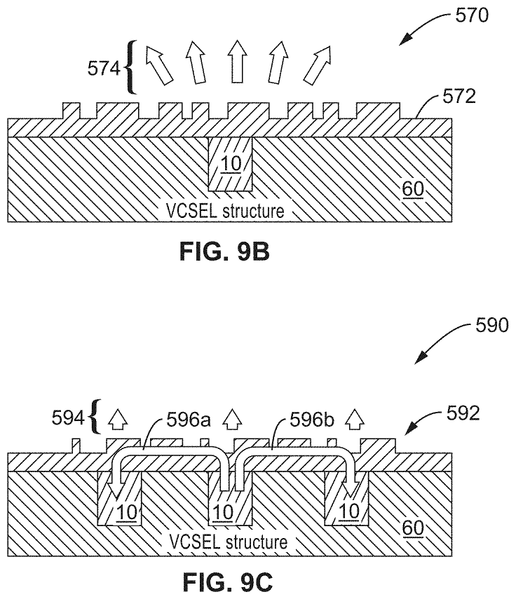

FIG. 9A through FIG. 9C illustrate example embodiments 550, 570 and 590 in which the VCSEL, or VCSEL array, has a grating which is configured to provide a variety of functionalities.

In FIG. 9A a sub-wavelength grating 552 is seen over VCSEL 10 to perform as a polarization, angle, mode or wavelength selective reflector with reflected optical output 556 and a smaller transmitted optical output 554. FIG. 9B shows a diffraction grating 572 over VCSEL 10, in which the grating supports multiple transmission orders as seen by the optical output 574, which may be utilized to engineer far field characteristics. Furthermore, FIG. 9C shows a grating 592 designed to provide optical coupling 596a, 596b between multiple VCSEL elements 10 of a VCSEL array, with reduced levels of transmitted optical output 594. In the figure a lateral optical coupling is seen between VCSELs in the array.

It should be appreciated that the structures of these top side gratings operating as a polarization, angle, mode or wavelength selective reflector can be combined with one another and with other embodiments described in the present disclosure.

3.2. Far-Field Engineering

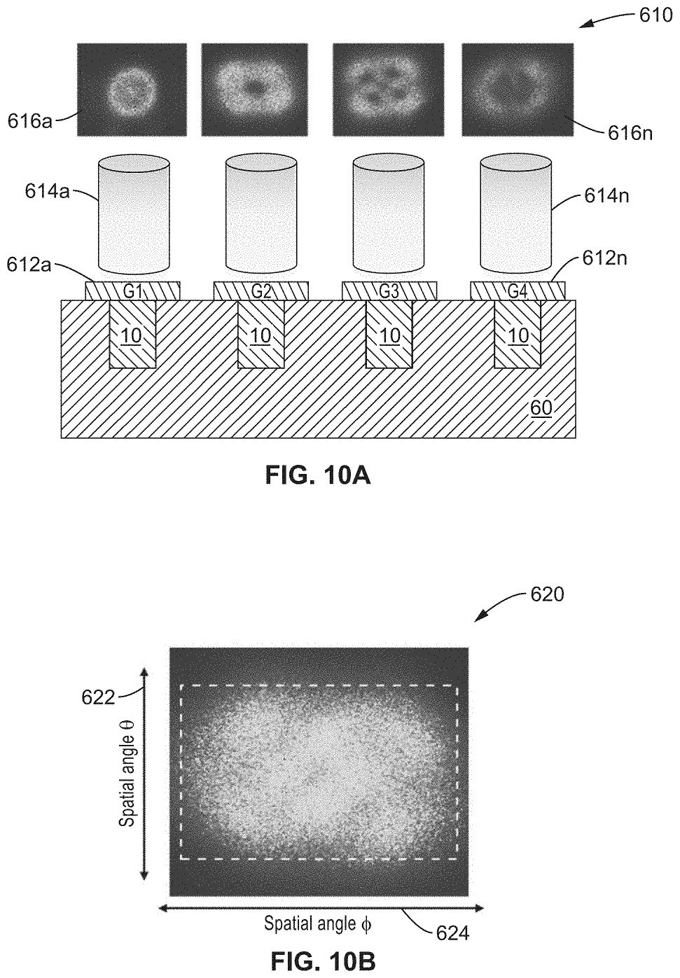

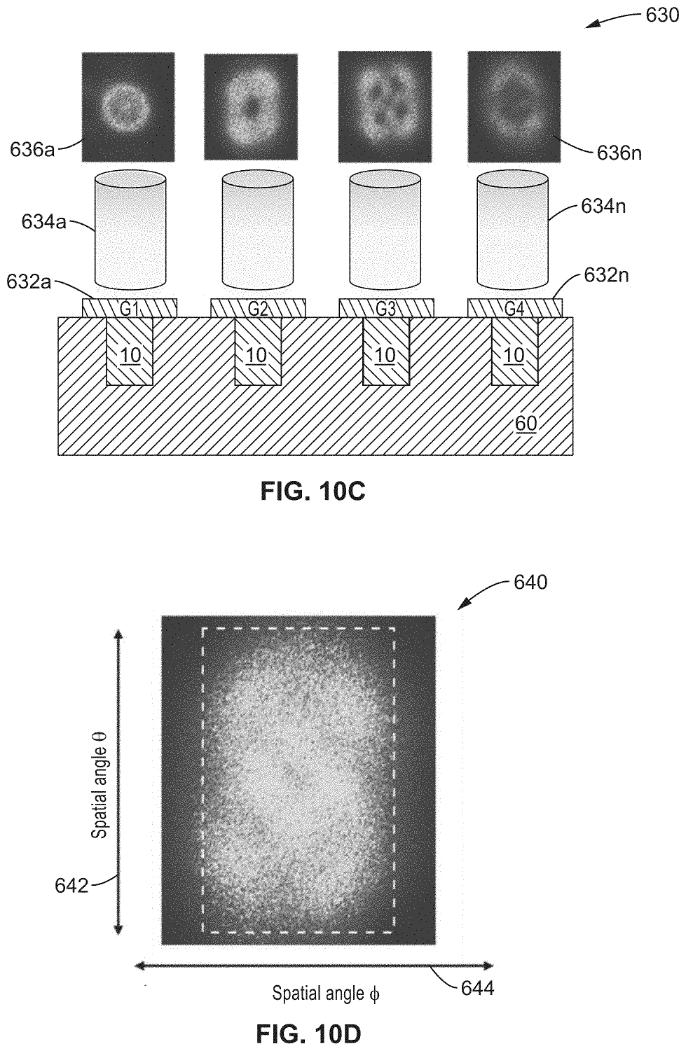

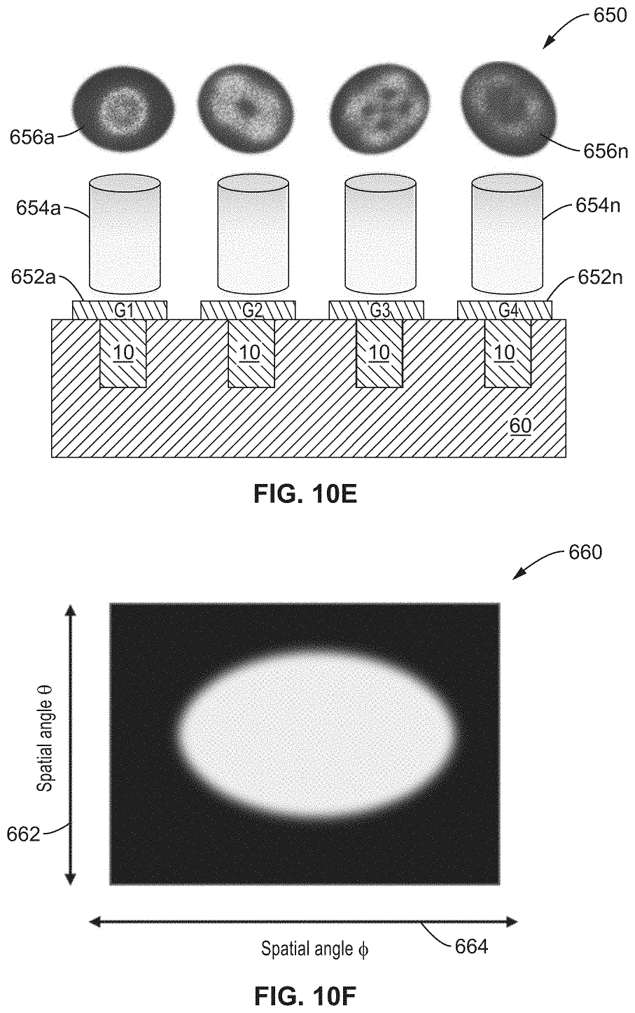

FIG. 10A through FIG. 10F illustrate example embodiments 610, 630 and 650 in which the grating of the VCSEL, or VCSEL array, has been configured to provide collective far field control, and showing renditions of example outputs 620, 640 and 660.

FIG. 10A shows VCSELs 10 in an array with gratings 612a through 612n which have been configured to control the far field pattern of the elements of the array seen in optical outputs 614a through 614n, with top view of example images 616a through 616n. FIG. 10B depicts the resultant far field pattern 620 and associated spatial angles θ 622 and ϕ 624 generated by the VCSEL arrays shown in FIG. 10A for the entire array which is characterized by a region of uniform high intensity, thus the engineered gratings on the individual VCSEL elements combine to act as an engineered diffuser.

FIG. 10C and FIG. 10D show that by rotating the individual gratings 632a through 632n of the VCSEL array seen in FIG. 10C by a common value then the far field pattern can be rotated as seen in FIG. 10D. The optical outputs 634a through 634n are seen in a top view 636a through 636n of FIG. 10C in which the respective rotations in relation to FIG. 10A can be seen. In FIG. 10D can be the far field pattern 640 showing the changes in spatial angles θ 642 and ϕ 644.

FIG. 10E and FIG. 10F illustrate that by rotating the individual gratings 652a through 652n of the VCSEL array by different values, then the characteristic of the far field pattern changes as seen in FIG. 10F. The optical outputs 654a through 654n are seen in a top view 656a through 656n of FIG. 10E in which the varied rotations in relation to the previous figures can be seen. FIG. 10F presents a far field pattern 660 showing the far field changes and respective spatial angles θ 662 and ϕ 664.

Individual elements of an array of VCSELs with engineered top side gratings of different designs can emit with different far field characteristics. An array based on multiple emitters with varying far field pattern can exhibit a designed far-field characteristic.

It should be appreciated that the structures of these top side gratings can be configured to provide collective far field control which can be combined with other embodiments described in the present disclosure.

3.3. Collimation or Divergence

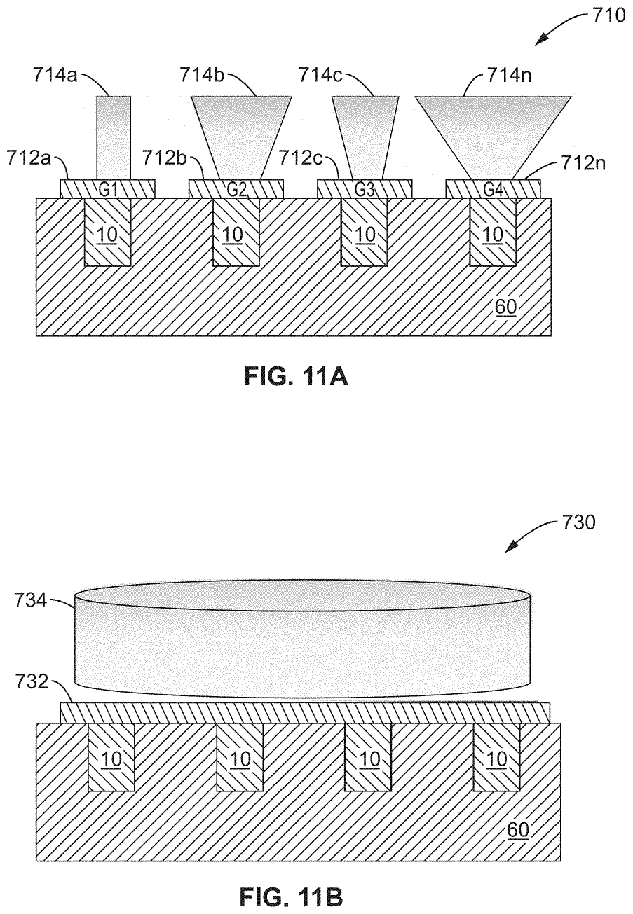

FIG. 11A through FIG. 11B illustrate example embodiments 710 and 730 in which the grating of the VCSEL, or VCSEL array, are configured for acting as a lens for collimation or divergence of emitted beams. In FIG. 11A VCSEL emitters 10 are each seen with individually configured gratings 712a through 712n that act as collimating or diverging lenses assembled into an array of emitters with optical output 714a through 714n which individually and/or collectively provides a beam with desired far field characteristics. In FIG. 11B multiple VCSEL emitters 10 in an array (e.g., one or more groups of emitters in the array or the entire array) share a spatially varying grating 732, which collimates or diffuses the emitted light 734 to obtain a desired far field characteristic.

On one or multiple top emitting VCSELs the engineered gratings act as collimating, focusing or diffusing optics. Engineered gratings with various designs may be aligned to individual emitters of an array of VCSELs or an engineered grating that may have a spatially varying design may cover multiple or all emitters of an array of emitters. It will be appreciated that the collimation or divergence of emitted beams as described above may be combined with one another and with other grating configurations described in the present disclosure.

It should be appreciated that the structures of these top side gratings can be configured to provide collimating or focusing or diverging or diffusion or combinations thereof which can be combined with other embodiments described in the present disclosure.

3.4. Polarization Control

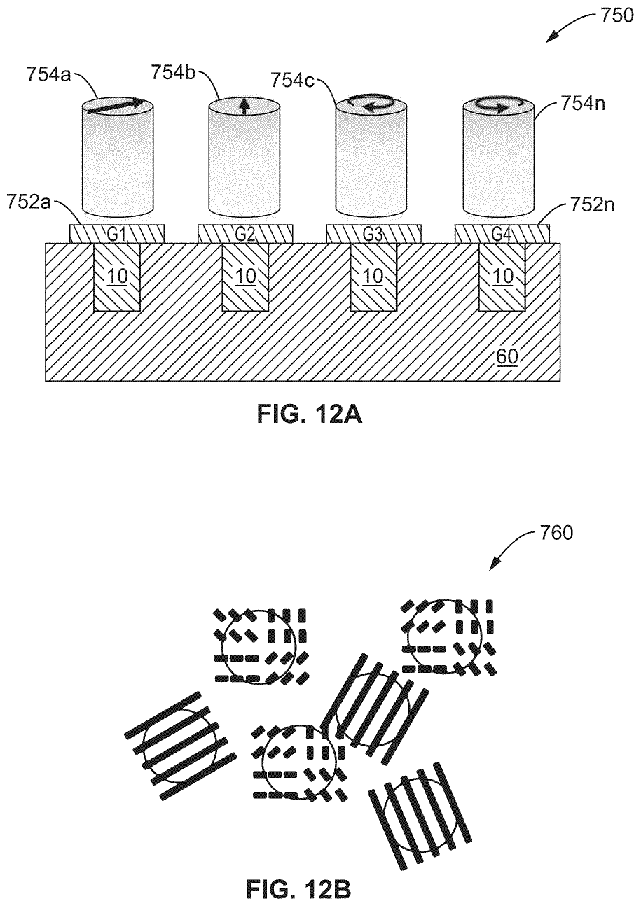

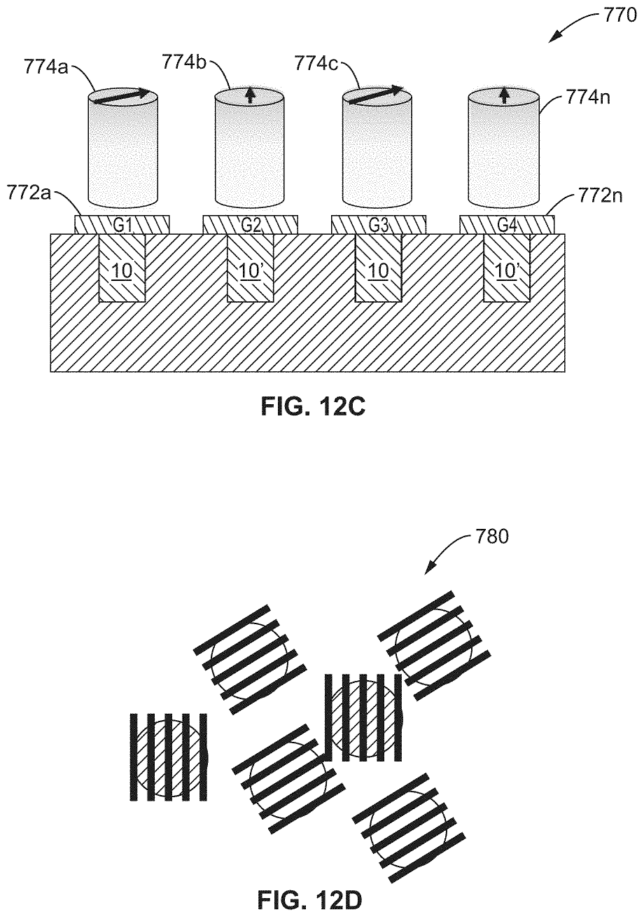

FIG. 12A through FIG. 12D illustrate example embodiments 750, 770 in which the grating of the VCSEL, or VCSEL array is configured for polarized emissions, examples of which are shown in example output patterns 760 and 780. FIG. 12A illustrates an array of VCSELs 10 that provide polarized emission. Gratings 752a through 752n are depicted as individually coupled over the VCSEL emitters to control the polarization (linear, circular or elliptical) of each optical output 754a through 754n. FIG. 12B depicts an example top view of pattern output 760 generated by the VCSEL in FIG. 12A.

FIG. 12C shows a VCSEL array in which different emitter groups have been configured with gratings 772a through 772n that determine their respective polarization and the emitter groups may be electrically addressed separately, enabling polarization switching of optical outputs 774a through 774n. In this example, grating 772a and 774c are in one group and grating 772b and 772d are in another group. FIG. 12D depicts a top view of example VCSEL array outputs 780, as generated by the VCSEL groups seen in FIG. 12C. It should be appreciated that the patterns depicted in these figures are provided by way of example and not limitation, as a wide range of patterns can be achieved by varying the polarization using a combination of linear, circular and/or elliptical control thereof.

On one or multiple top emitting VCSELs the engineered gratings act as a polarizer that can either control the polarization (linear, circular or elliptical) of individual emitters or groups of emitters that may or may not be electrically addressed separately.

It should be appreciated that the polarization effects can be combined with one another and with other embodiments described in the present disclosure without limitation.

3.5. Beam Diffusing

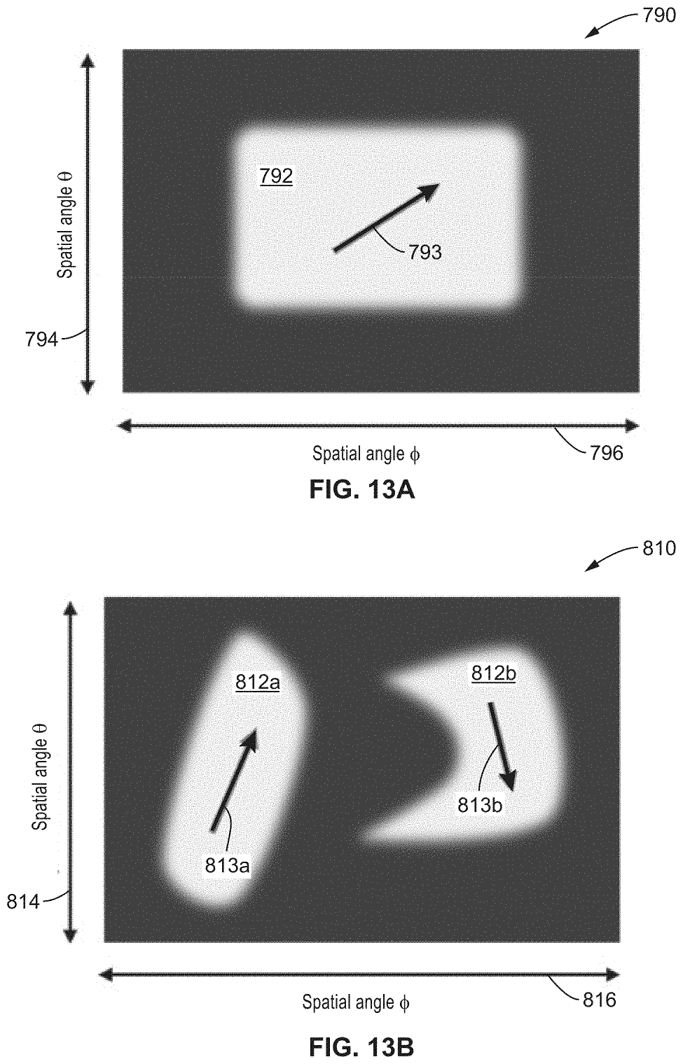

FIG. 13A and FIG. 13B illustrate example embodiments 790 and 810 in which the grating of the VCSEL, or VCSEL array is configured as a combination of polarizer and diffuser with far field images shown of the results. In particular, the far field intensity may be configured to generate a regular shaped single region 792 of high uniform intensity with defined polarization 793 as seen in FIG. 13A, or having one or more different high intensity uniform regions 812a, 812b (and so forth) generated with designed positions and shapes as well as defined polarizations 813a, 813b as seen in FIG. 13B. The spatial angles 0 794 and ϕ 796 are seen for FIG. 13A, with spatial angles θ 814 and ϕ 816 seen for FIG. 13B.

Thus, one or multiple top emitting VCSELs with engineered gratings are designed to collectively emit light in a far field pattern that is characterized by a high uniform intensity emitted at certain spatial angles and a low or no intensity emitted at other special angles.

It should be appreciated that the structures of these top side gratings can be configured to provide beam diffusing to create regular shaped single or multiple regions of high uniform intensity with defined polarization or combinations thereof which can also be combined with other embodiments described in the present disclosure.

3.6. Diffraction Optical Elements for Structured Light

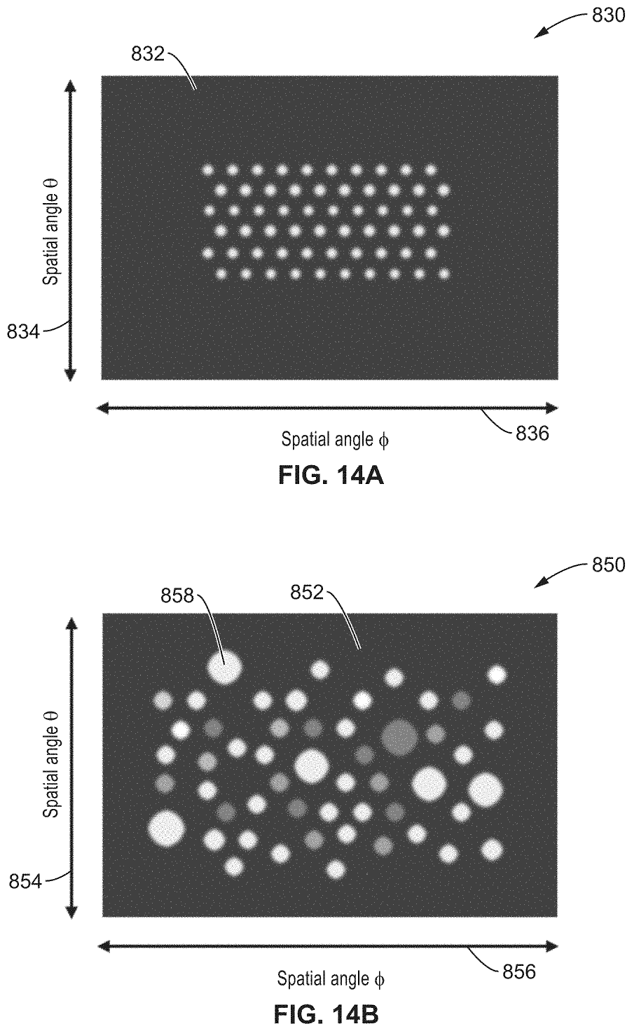

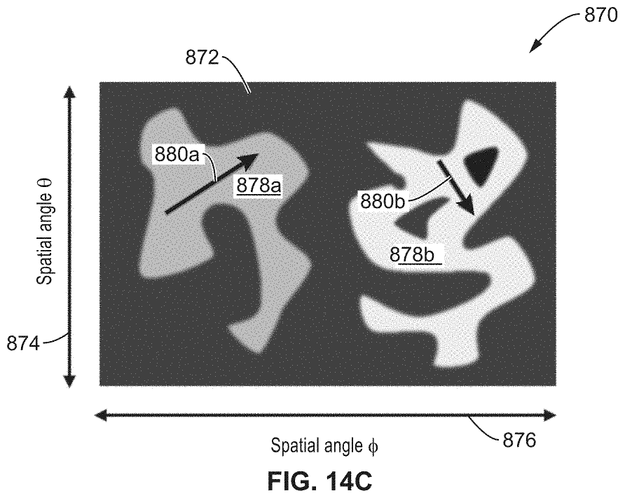

FIG. 14A through FIG. 14C illustrate example embodiments 830, 850 and 870 in which the grating of the VCSELs in the VCSEL array are configured having a structured far field pattern to produce the exemplified far field patterns. Far field intensity patterns are exemplified to provide a number of identically shaped non-overlapping regions of high and same relative intensity and defined polarization as seen in 832 of FIG. 14A having spatial angles θ 834 and ϕ 836. Alternatively, or additionally, a number of non-overlapping areas of high intensity with designed shape and relative intensity and designed polarizations are seen in 852 of FIG. 14B, having spatial angles θ 854 and ϕ 856. Alternatively, or additionally, the pattern can be configured with a number of non-overlapping areas of high intensity with designed shape, relative intensity and polarization that enclose regions with low or no intensity as seen in 872 as shapes 878a, 878b and polarizations 880a, 880b as seen in FIG. 14C.

Thus, one or multiple top emitting VCSELs with engineered gratings are designed to collectively emit light in a far field pattern that is characterized by a number of non-overlapping areas of high intensity, with engineered relative intensities and other areas of low or no intensity.

It should be appreciated that the structures of these top side gratings can be configured to provide control of far field intensity patterns, such as providing identically or different non-overlapping regions of the same or different relative intensities and polarizations, and can also be combined with other embodiments described in the present disclosure.

3.7. Beam Steering.

The following describes the use of beam steering in particular and dynamically changing far field patterns in general. An array of top emitting VSCELs with engineered gratings has a number of emitter groups that can be electrically addressed separate from one another. Each such group of top emitting VCSELs with engineered gratings is designed to emit light in a different far field pattern. Each of the emitter groups has a far field characterized by a number of non-overlapping areas of high intensity, with engineered relative intensities and other areas of low or no intensity.

It should be appreciated that the use of beam steering for dynamically changing VCSEL outputs and more particularly the far field patterns can also be combined with other embodiments described in the present disclosure.

From the description herein, it will be appreciated that the present disclosure encompasses multiple embodiments which include, but are not limited to, the following:

1. A vertical cavity surface emitting laser (VCSEL) apparatus, comprising: (a) at least one vertical cavity surface emitting laser (VCSEL) comprising: (i) a lower electrode; (ii) a lower distributed Bragg reflector (DBR) associated with said lower electrode; (iii) a quantum well structure over said lower DBR; (iv) an upper reflector over said quantum well structure; (v) an upper electrode; and (b) a high contrast grating integrated over the top side surface of said VCSEL as a top side high contrast grating which is configured as an optically active structure for modifying emissions of said at least one VCSEL to enable optical functionalities.

2. A vertical cavity surface emitting laser (VCSEL) apparatus, comprising: (a) a vertical cavity surface emitting laser (VCSEL) array in which each VCSEL comprises: (a)(i) a lower electrode; (a)(ii) a lower distributed Bragg reflector (DBR) associated with said lower electrode; (a)(iii) a quantum well structure over said lower DBR; (a)(iv) an upper reflector over said quantum well structure; (a)(v) an upper electrode; and (b) at least one high contrast grating integrated over the top side surface of said VCSEL array, or its individual VCSELs, as a top side high contrast grating which is configured as an optically active structure for modifying emissions of said at least one VCSEL to enable optical functionalities; and (c) wherein said top side high contrast gratings (HCGs) are integrated to control far field patterns of the elements of the array to provide far field control of portions of the VCSEL array or the whole VCSEL array.

3. A method of extending functionalities of a vertical cavity surface emitting laser (VCSEL), comprising: (a) fabricating at least one vertical cavity surface emitting laser (VCSEL) having a lower electrode, lower distributed Bragg reflector (DBR), a quantum well structure, an upper reflector over said quantum well structure, a planar top side surface over the VCSEL, and an upper electrode; and (b) integrating a high contrast grating into the planar top side surface of said VCSEL as a top side high contrast grating which is configured as an optically active structure for modifying emissions of said at least one VCSEL to enable optical functionalities.

4. A vertical cavity surface emitting laser (VCSEL) apparatus, comprising: a substrate and a first electrode; a lower distributed Bragg reflector (DBR); a quantum well structure over said lower DBR; an upper reflector comprising a top side high contrast grating (HCG), over said quantum well structure; and an upper electrode over said upper reflector.

5. The apparatus or method of any preceding embodiment, wherein said top side high contrast grating (HCG) has a regular, chirped or irregular shape.

6. The apparatus or method of any preceding embodiment, wherein said top side high contrast grating (HCG) has 1D, 2D or 3D periodicity, is quasi-periodic, or is aperiodic.

7. The apparatus or method of any preceding embodiment, wherein said top side high contrast grating (HCG) has a regular, chirped or irregular shape and has 1D, 2D or 3D periodicity, is quasi-periodic, or is aperiodic.

8. The apparatus or method of any preceding embodiment, wherein said at least one vertical cavity surface emitting laser (VCSEL) comprises an array of VCSELs.

9. The apparatus or method of any preceding embodiment, wherein said top side high contrast grating (HCG) is configured to cover an entire emission area of each said VCSEL within the array of said VCSELs.

10. The apparatus or method of any preceding embodiment, wherein said top side high contrast grating (HCG) is aligned with each VCSEL emitter within the array of said VCSELs.

11. The apparatus or method of any preceding embodiment, wherein said top side high contrast grating (HCG) is intentionally misaligned with one or more VCSEL emitters within the array of said VCSELs.

12. The apparatus or method of any preceding embodiment, wherein said top side high contrast grating (HCG) is configured to cover different sections of the array of said VCSELs.

13. The apparatus or method of any preceding embodiment, wherein each of said VCSELs in the array of VCSELS can be configured for being electrically addressed collectively, or electrically addressed in groups within the VCSEL array, or electrically addressed separately.

14. The apparatus or method of any preceding embodiment, wherein said top side high contrast grating (HCG) is either etched into the existing material of the at least one vertical cavity surface emitting laser (VCSEL) structure or by depositing and patterning an additional layer of material as a top grating layer.

15. The apparatus or method of any preceding embodiment, wherein said top side high contrast grating (HCG) comprises a high contrast grating fabricated of material selected from the group of grating materials consisting of GaAs, AlGaAs, SiNx, SiO2, InGaP, or combinations thereof.

16. The apparatus or method of any preceding embodiment, wherein said top side high contrast grating (HCG) comprises a high index grating layer n2 on top of a low index layer n1 and interfacing the free space low index area n3.

17. The apparatus or method of any preceding embodiment, wherein said top side high contrast grating (HCG) comprises a high index grating layer n2 on top of a low index layer n1 and covered by a planar layer of low index material n3.

18. The apparatus or method of any preceding embodiment, wherein said top side high contrast grating (HCG) is an engineered grating in which areas of materials with high optical refractive index nᵢ are interfacing other areas of materials with low optical refractive index ni so that regions of either group of materials surround regions of the other group of materials.

19. The apparatus or method of any preceding embodiment, wherein said top side high contrast grating (HCG) is configured with a chirped period at constant bar width.

20. The apparatus or method of any preceding embodiment, wherein said top side high contrast grating (HCG) is configured with a chirped period and varying bar widths.

21. The apparatus or method of any preceding embodiment, wherein said top side high contrast grating (HCG) is configured with a constant period and varying bar width.

22. The apparatus or method of any preceding embodiment, wherein said top side high contrast grating (HCG) is configured with a radially chirped grating that may be used as a lens.

23. The apparatus or method of any preceding embodiment, wherein said top side high contrast grating (HCG) is configured with different grating periods that determine the angle of separation of the reflective and transmissive orders.

24. The apparatus or method of any preceding embodiment, wherein said top side high contrast grating (HCG) comprises a diffractive grating with many reflective and transmissive orders.

25. The apparatus or method of any preceding embodiment, wherein said top side high contrast grating (HCG) comprises a diffractive grating with few reflective and transmissive orders.

26. The apparatus or method of any preceding embodiment, wherein said top side high contrast grating (HCG) is configured with an engineered period that provides in-plane coupling via the 1st and minus 1st orders.

27. The apparatus or method of any preceding embodiment, wherein said top side high contrast grating (HCG) is configured with a sub-wavelength period.

28. The apparatus or method of any preceding embodiment, wherein said top side high contrast grating (HCG) is configured to control relative amplitudes of the transmitted and reflected orders.

29. The apparatus or method of any preceding embodiment, wherein said relative amplitudes are selected orders which are suppressed or enhanced, or have a number of orders having equal amplitude, or enhancement of a number of orders and at the same time suppression of another number of orders.

30. The apparatus or method of any preceding embodiment, wherein the at least one said vertical cavity surface emitting laser (VCSEL) comprises a VCSEL array over which said top side high contrast gratings (HCGs) are integrated to control far field patterns of the elements of the array to provide far field control of portions of the VCSEL array or the whole VCSEL array.

31. The apparatus or method of any preceding embodiment, wherein said apparatus is configured to provide far field control by rotating individual top side high contrast gratings (HCGs) by a common value so that the far field pattern can be rotated.

32. The apparatus or method of any preceding embodiment, wherein said apparatus is configured to provide far field control by rotating individual top side high contrast gratings (HCGs) by different values, as well as configuring the gratings with different periods, or widths, or materials, or combinations thereof, to change far field pattern characteristics.

33. The apparatus or method of any preceding embodiment, wherein the at least one said vertical cavity surface emitting laser (VCSEL) comprises a VCSEL array over which said top side high contrast gratings (HCGs) are integrated so that individual VCSEL elements within the VCSEL array combine to act as an engineered diffuser so that a far field pattern of the entire array is characterized by a region of uniform high intensity.

34. The apparatus or method of any preceding embodiment, wherein the at least one said vertical cavity surface emitting laser (VCSEL) comprises a VCSEL array over which said top side high contrast gratings (HCGs) are configured as a lens for collimating or diverging an emitted beam of the VCSEL within the VCSEL array.

35. The apparatus or method of any preceding embodiment, wherein the at least one said vertical cavity surface emitting laser (VCSEL) comprises a VCSEL array over which said top side high contrast gratings (HCGs) are integrated to have individually engineered gratings configured as collimating or diverging lenses so that the VCSEL array emits a beam having desired far field characteristics.

36. The apparatus or method of any preceding embodiment, wherein the at least one said vertical cavity surface emitting laser (VCSEL) comprises a VCSEL array over which said top side high contrast gratings (HCGs) are configured so that multiple emitters in the VCSEL array share a spatially varying high contrast grating, which collimates or diffuses the emitted light to obtain a desired far field characteristic.

37. The apparatus or method of any preceding embodiment, wherein said top side high contrast grating (HCG) is configured to generate polarized emissions.

38. The apparatus or method of any preceding embodiment, wherein the at least one said vertical cavity surface emitting laser (VCSEL) comprises a VCSEL array over which said top side high contrast gratings (HCGs) are integrated; and wherein said polarized emissions are generated by the VCSEL array acting as emitters having engineered gratings that control the polarization to be linear, circular and/or elliptical for a number of individual VCSEL elements within the VCSEL array.

39. The apparatus or method of any preceding embodiment, wherein the at least one said vertical cavity surface emitting laser (VCSEL) comprises a VCSEL array over which said top side high contrast gratings (HCGs) are integrated; wherein said polarized emissions are generated by said VCSELs in the VCSEL array in which different groups of VCSELs have engineered gratings that determine their respective polarization and the emitter groups; and wherein each of said VCSELs in the array of VCSELS can be configured for being electrically addressed collectively, or electrically addressed separately, for enabling polarization switching.

40. The apparatus or method of any preceding embodiment, wherein the at least one said vertical cavity surface emitting laser (VCSEL) comprises a VCSEL array over which said top side high contrast gratings (HCGs) are integrated; and wherein said VCSEL array is configured to provide far field control with the top side high contrast gratings configured to operate as a polarizer and diffuser, to change far field intensity into either (a) a regular shaped single region of high uniform intensity with defined polarization or (b) a number of high intensity uniform regions with designed positions and shapes and defined polarizations.

41. The apparatus or method of any preceding embodiment, wherein the at least one said vertical cavity surface emitting laser (VCSEL) comprises a VCSEL array over which said top side high contrast gratings (HCGs) are integrated; and wherein said VCSEL array is configured to provide far field control with each VCSEL having a top side high contrast grating (HCG) configured so that a structured far field pattern is generated with a far field intensity which is either (a) a number of identically shaped non-overlapping regions of high and same relative intensity and defined polarization, or (b) a number of non-overlapping areas of high intensity with designed shape and relative intensity and designed polarizations, or (c) a number of non-overlapping areas of high intensity with designed shape, relative intensity and polarization that enclose regions with low or no intensity.

42. The apparatus or method of any preceding embodiment, wherein said apparatus is configured for 3D sensing applications.

43. The apparatus or method of any preceding embodiment, wherein said top side high contrast grating (HCG) is configured to operate as: (a) as optical element shaping the characteristics of the emitted far field of the array, or (b) as polarization, angle, mode or wavelength selective mirror of the cavity, or (c) as optical coupler between multiple elements of the array, or (d) as any combination of the above.

44. The apparatus or method of any preceding embodiment, wherein the at least one said vertical cavity surface emitting laser (VCSEL) comprises a VCSEL array over which said top side high contrast gratings (HCGs) are integrated; and wherein said apparatus is configured to provide beam steering and polarization switching by electrically addressing either individually, and/or in groups, the VCSELs within the VCSEL.

45. The apparatus or method of any preceding embodiment, wherein said top side high contrast grating (HCG) comprises either a subwavelength HCG having a period less than the wavelength of the VCSEL, or is a diffractive HCG having a period greater than or equal to the wavelength of the VCSEL.

46. The apparatus or method of any preceding embodiment, wherein said top side high contrast grating (HCG) comprises periodicity in 1D, 2D or 3D, quasi-periodic, aperiodic, and/or with shapes being regular, chirped or irregular.

47. The apparatus or method of any preceding embodiment, wherein said top side high contrast grating (HCG) is configured to cover the entire emission area of each VCSEL within an array of VCSELs.

48. The apparatus or method of any preceding embodiment, wherein said top side high contrast grating (HCG) is aligned with each VCSEL emitter within an array of VCSELs.

49. The apparatus or method of any preceding embodiment, wherein said top side high contrast grating (HCG) is intentionally misaligned with the VCSEL emitters.

50. The apparatus or method of any preceding embodiment, wherein said top side high contrast grating (HCG) is configured to cover different sections of an array of said VCSEL apparatus, which may or may not be electrically addressed separately.

51. The apparatus or method of any preceding embodiment, wherein said top side high contrast grating (HCG) is either etched into the existing material of the VSCEL structure or by depositing and patterning an additional layer of material as a top grating layer.

52. The apparatus or method of any preceding embodiment, wherein said top side high contrast grating (HCG) comprises a high contrast grating fabricated of material selected from the group of grating materials consisting of GaAs, AlGaAs, SiNx, SiO2, InGaP, or combinations thereof.

53. The apparatus or method of any preceding embodiment, wherein said top side high contrast grating (HCG) comprises a high index grating layer n2 on top of a low index layer n1 and interfacing the free space low index area n3.

54. The apparatus or method of any preceding embodiment, wherein said top side high contrast grating (HCG) is covered by a planar layer of low index material n3.

55. The apparatus or method of any preceding embodiment, wherein said top side high contrast grating (HCG) is conformally covered by a low index later n3.

56. The apparatus or method of any preceding embodiment, wherein said top side high contrast grating (HCG) is an engineered grating in which areas of materials with high optical refractive index nj are interfacing other areas of materials with low optical refractive index ni so that regions of either group of materials surround regions of the other group of materials.

57. The apparatus or method of any preceding embodiment, wherein said top side high contrast grating (HCG) is configured with a chirped period at constant bar width.

58. The apparatus or method of any preceding embodiment, wherein said top side high contrast grating (HCG) is configured with a chirped period and varying bar widths.

59. The apparatus or method of any preceding embodiment, wherein said top side high contrast grating (HCG) is configured with a constant period and varying bar width.

60. The apparatus or method of any preceding embodiment, wherein said top side high contrast grating (HCG) is configured with a radially chirped grating that may be used as a lens.

61. The apparatus or method of any preceding embodiment, wherein said top side high contrast grating (HCG) is configured with different grating periods that determine the angle of separation of the reflective and transmissive orders.

62. The apparatus or method of any preceding embodiment, wherein said top side high contrast grating (HCG) comprises a diffractive grating with many reflective and transmissive orders.

63. The apparatus or method of any preceding embodiment, wherein said top side high contrast grating (HCG) comprises a diffractive grating with few reflective and transmissive orders.

64. The apparatus or method of any preceding embodiment, wherein said top side high contrast grating (HCG) is configured with an engineered period that provides in-plane coupling via the 1st and minus 1st orders.

65. The apparatus or method of any preceding embodiment, wherein said top side high contrast grating (HCG) is configured with an engineered period comprises a sub wavelength.

66. The apparatus or method of any preceding embodiment, wherein said top side high contrast grating (HCG) is configured with relative amplitudes of the transmitted and reflected orders.

67. The apparatus or method of any preceding embodiment, wherein said relative amplitudes are selected orders which are suppressed or enhanced, or have a number of orders having equal amplitude, or enhancement of a number of orders and at the same time suppression of another number of orders.

68. The apparatus or method of any preceding embodiment, wherein said apparatus is configured with an array of emitters having engineered top side high contrast gratings (HCGs) that control the far field pattern of the elements of the array to provide far field control.

69. The apparatus or method of any preceding embodiment, wherein said apparatus is configured so that individual VCSEL elements within an array of VCSELs combine to act as an engineered diffuser so that a far field pattern of the entire array is characterized by a region of uniform high intensity, so that engineered gratings on individual VCSEL elements combine to operate as an engineered diffuser.

70. The apparatus or method of any preceding embodiment, wherein said apparatus is configured to provide far field control by rotating individual top side high contrast gratings (HCGs) by a common value so that the far field pattern can be rotated.

71. The apparatus or method of any preceding embodiment, wherein said apparatus is configured to provide far field control by rotating individual top side high contrast gratings (HCGs) by different values so that the characteristic far field pattern changes.

72. The apparatus or method of any preceding embodiment, wherein said top side high contrast grating (HCG) is configured as a lens for collimating or diverging an emitted beam of the VCSEL within a VCSEL array.

73. The apparatus or method of any preceding embodiment, wherein said top side high contrast grating (HCG) is configured in each VCSEL within an VCSEL array having emitters with individual engineered grating designs that act as collimating or diverging lenses that are assembled into an array of emitters that emits a beam of desired far field characteristic.

74. The apparatus or method of any preceding embodiment, wherein said top side high contrast grating (HCG) is configured in each VCSEL within an VCSEL array in which multiple emitters in the VCSEL array share a spatially varying high contrast grating, which collimates or diffuses the emitted light to obtain a desired far field characteristic.

75. The apparatus or method of any preceding embodiment, wherein said top side high contrast grating (HCG) is configured to generate polarized emissions.

76. The apparatus or method of any preceding embodiment, wherein said polarized emissions are generated by an array of said VCSELs acting as emitters having engineered gratings that control the polarization to be linear, circular and/or elliptical of a number of individual VCSEL elements.

77. The apparatus or method of any preceding embodiment, wherein said polarized emissions are generated by an array of said VCSELs in which different groups of VCSEL emitters have engineered gratings that determine their respective polarization and the emitter groups may be electrically addressed separately, enabling polarization switching.

78. The apparatus or method of any preceding embodiment, wherein said apparatus is configured to provide far field control by said VCSEL within a VCSEL array by engineering the top side high contrast gratings(HCGs) to operate as a polarizer and diffuser, to change far field intensity into either (a) a regular shaped single region of high uniform intensity with defined polarization or (b) a number of high intensity uniform regions with designed positions and shapes and defined polarizations.

79. The apparatus or method of any preceding embodiment, wherein said apparatus is configured to provide far field control by said VCSEL within a VCSEL array in which each VCSEL has an engineered top side high contrast grating (HCG) so that a structured far field pattern is generated with a far field intensity which is (a) a number of identically shaped non-overlapping regions of high and same relative intensity and defined polarization, or (b) a number of non-overlapping areas of high intensity with designed shape and relative intensity and designed polarizations, or (c) a number of non-overlapping areas of high intensity with designed shape, relative intensity and polarization that enclose regions with low or no intensity.

80. The apparatus or method of any preceding embodiment, wherein said apparatus is configured for 3D sensing applications.

81. The apparatus or method of any preceding embodiment, wherein said top side high contrast grating (HCG) is configured to operate as: (1) as optical element shaping the characteristics of the emitted far field of the array, or (2) as polarization, angle, mode or wavelength selective mirror of the cavity, or (3) as optical coupler between multiple elements of the array, or (4) as any combination of the above.

82. The apparatus or method of any preceding embodiment, wherein said apparatus is configured to provide beam steering and polarization switching by electrically addressing groups of VCSELs within an array of VCSELs separately.

83. Each and every embodiment of the technology described herein, as well as any aspect, component, or element of any embodiment described herein, and any combination of aspects, components or elements of any embodiment described herein.

4. General Scope of Embodiments

As used herein, the singular terms “a,” “an,” and “the” may include plural referents unless the context clearly dictates otherwise. Reference to an object in the singular is not intended to mean “one and only one” unless explicitly so stated, but rather “one or more.”

Phrasing constructs, such as “A, B and/or C”, within the present disclosure describe where either A, B, or C can be present, or any combination of items A, B and C. Phrasing constructs indicating, such as “at least one of” followed by listing group of elements, indicates that at least one of these group elements is present, which includes any possible combination of these listed elements as applicable.

References in this specification referring to “an embodiment”, “at least one embodiment” or similar embodiment wording indicates that a particular feature, structure, or characteristic described in connection with a described embodiment is included in at least one embodiment of the present disclosure. Thus, these various embodiment phrases are not necessarily all referring to the same embodiment, or to a specific embodiment which differs from all the other embodiments being described. The embodiment phrasing should be construed to mean that the particular features, structures, or characteristics of a given embodiment may be combined in any suitable manner in one or more embodiments of the disclosed apparatus, system or method.

As used herein, the term “set” refers to a collection of one or more objects. Thus, for example, a set of objects can include a single object or multiple objects.

As used herein, the terms “substantially” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” aligned can refer to a range of angular variation of less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

All structural and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A vertical cavity surface emitting laser (VCSEL) apparatus, comprising:
(a) at least one vertical cavity surface emitting laser (VCSEL) comprising:
(i) a lower electrode;
(ii) a lower distributed Bragg reflector (DBR) associated with said lower electrode;
(iii) a quantum well structure over said lower DBR;
(iv) an upper reflector over said quantum well structure;
(v) an upper electrode; and
(b) a high contrast grating integrated over the top side surface of said VCSEL as a top side high contrast grating which is configured as an optically active structure for modifying emissions of said at least one VCSEL to enable optical functionalities.

2. The apparatus of claim 1, wherein said top side high contrast grating (HCG) has a regular, chirped or irregular shape.

3. The apparatus of claim 1, wherein said top side high contrast grating (HCG) has 1D, 2D or 3D periodicity, is quasi-periodic, or is aperiodic.

4. The apparatus of claim 3, wherein said top side high contrast grating (HCG) has a regular, chirped or irregular shape.

5. The apparatus of claim 1, wherein said at least one vertical cavity surface emitting laser (VCSEL) comprises an array of VCSELs.

6. The apparatus of claim 5, wherein said top side high contrast grating (HCG) is configured to cover an entire emission area of each said VCSEL within the array of said VCSELs.

7. The apparatus of claim 5, wherein said top side high contrast grating (HCG) is aligned with each VCSEL emitter within the array of said VCSELs.

8. The apparatus of claim 5, wherein said top side high contrast grating (HCG) is intentionally misaligned with one or more VCSEL emitters within the array of said VCSELs.

9. The apparatus of claim 5, wherein said top side high contrast grating (HCG) is configured to cover different sections of the array of said VCSELs.

10. The apparatus of claim 5, wherein each of said VCSELs in the array of VCSELS can be configured for being electrically addressed collectively, or electrically addressed in groups within the VCSEL array, or electrically addressed separately.

11. The apparatus of claim 1, wherein said top side high contrast grating (HCG) is either etched into the existing material of the at least one vertical cavity surface emitting laser (VCSEL) structure or by depositing and patterning an additional layer of material as a top grating layer.

12. The apparatus of claim 1, wherein said top side high contrast grating (HCG) comprises a high contrast grating fabricated of material selected from the group of grating materials consisting of GaAs, AlGaAs, SiNx, SiO₂, InGaP, or combinations thereof.

13. The apparatus of claim 1, wherein said top side high contrast grating (HCG) comprises a high index grating layer n2 on top of a low index layer n1 and interfacing the free space low index area n3.

14. The apparatus of claim 1, wherein said top side high contrast grating (HCG) comprises a high index grating layer n2 on top of a low index layer n1 and covered by a planar layer of low index material n3.

15. The apparatus of claim 1, wherein said top side high contrast grating (HCG) is an engineered grating in which areas of materials with high optical refractive index nⱼ are interfacing other areas of materials with low optical refractive index nᵢ so that regions of either group of materials surround regions of the other group of materials.

16. The apparatus of claim 1, wherein said top side high contrast grating (HCG) is configured with a chirped period at constant bar width.

17. The apparatus of claim 1, wherein said top side high contrast grating (HCG) is configured with a chirped period and varying bar widths.

18. The apparatus of claim 1, wherein said top side high contrast grating (HCG) is configured with a constant period and varying bar width.

19. The apparatus of claim 1, wherein said top side high contrast grating (HCG) is configured with a radially chirped grating that may be used as a lens.

20. The apparatus of claim 1, wherein said top side high contrast grating (HCG) is configured with different grating periods that determine the angle of separation of the reflective and transmissive orders.

21. The apparatus of claim 20, wherein said top side high contrast grating (HCG) comprises a diffractive grating with many reflective and transmissive orders.

22. The apparatus of claim 20, wherein said top side high contrast grating (HCG) comprises a diffractive grating with few reflective and transmissive orders.

23. The apparatus of claim 20, wherein said top side high contrast grating (HCG) is configured with an engineered period that provides in-plane coupling via the 1st and minus 1st orders.

24. The apparatus of claim 20, wherein said top side high contrast grating (HCG) is configured with a sub-wavelength period.

25. The apparatus of claim 1, wherein said top side high contrast grating (HCG) is configured to control relative amplitudes of the transmitted and reflected orders.

26. The apparatus of claim 25, wherein said relative amplitudes are selected orders which are suppressed or enhanced, or have a number of orders having equal amplitude, or enhancement of a number of orders and at the same time suppression of another number of orders.

27. The apparatus of claim 1, wherein the at least one said vertical cavity surface emitting laser (VCSEL) comprises a VCSEL array over which said top side high contrast gratings (HCGs) are integrated to control far field patterns of the elements of the array to provide far field control of portions of the VCSEL array or the whole VCSEL array.

28. The apparatus of claim 27, wherein said apparatus is configured to provide far field control by rotating individual top side high contrast gratings (HCGs) by a common value so that the far field pattern can be rotated.

29. The apparatus of claim 27, wherein said apparatus is configured to provide far field control by rotating individual top side high contrast gratings (HCGs) by different values, as well as configuring the gratings with different periods, or widths, or materials, or combinations thereof, to change far field pattern characteristics.

30. The apparatus of claim 1, wherein the at least one said vertical cavity surface emitting laser (VCSEL) comprises a VCSEL array over which said top side high contrast gratings (HCGs) are integrated so that individual VCSEL elements within the VCSEL array combine to act as an engineered diffuser so that a far field pattern of the entire array is characterized by a region of uniform high intensity.

31. The apparatus of claim 1, wherein the at least one said vertical cavity surface emitting laser (VCSEL) comprises a VCSEL array over which said top side high contrast gratings (HCGs) are configured as a lens for collimating or diverging an emitted beam of the VCSEL within the VCSEL array.

32. The apparatus of claim 1, wherein the at least one said vertical cavity surface emitting laser (VCSEL) comprises a VCSEL array over which said top side high contrast gratings (HCGs) are integrated to have individually engineered gratings configured as collimating or diverging lenses so that the VCSEL array emits a beam having desired far field characteristics.

33. The apparatus of claim 1, wherein the at least one said vertical cavity surface emitting laser (VCSEL) comprises a VCSEL array over which said top side high contrast gratings (HCGs) are configured so that multiple emitters in the VCSEL array share a spatially varying high contrast grating, which collimates or diffuses the emitted light to obtain a desired far field characteristic.

34. The apparatus of claim 1, wherein said top side high contrast grating (HCG) is configured to generate polarized emissions.

35. The apparatus of claim 34:
wherein the at least one said vertical cavity surface emitting laser (VCSEL) comprises a VCSEL array over which said top side high contrast gratings (HCGs) are integrated; and
wherein said polarized emissions are generated by the VCSEL array acting as emitters having engineered gratings that control the polarization to be linear, circular and/or elliptical for a number of individual VCSEL elements within the VCSEL array.

36. The apparatus of claim 34:
wherein the at least one said vertical cavity surface emitting laser (VCSEL) comprises a VCSEL array over which said top side high contrast gratings (HCGs) are integrated;
wherein said polarized emissions are generated by said VCSELs in the VCSEL array in which different groups of VCSELs have engineered gratings that determine their respective polarization and the emitter groups; and
wherein each of said VCSELs in the array of VCSELS can be configured for being electrically addressed collectively, or electrically addressed separately, for enabling polarization switching.

37. The apparatus of claim 1:
wherein the at least one said vertical cavity surface emitting laser (VCSEL) comprises a VCSEL array over which said top side high contrast gratings (HCGs) are integrated; and
wherein said VCSEL array is configured to provide far field control with the top side high contrast gratings configured to operate as a polarizer and diffuser, to change far field intensity into either (a) a regular shaped single region of high uniform intensity with defined polarization or (b) a number of high intensity uniform regions with designed positions and shapes and defined polarizations.

38. The apparatus of claim 1:
wherein the at least one said vertical cavity surface emitting laser (VCSEL) comprises a VCSEL array over which said top side high contrast gratings (HCGs) are integrated; and
wherein said VCSEL array is configured to provide far field control with each VCSEL having a top side high contrast grating (HCG) configured so that a structured far field pattern is generated with a far field intensity which is either (a) a number of identically shaped non-overlapping regions of high and same relative intensity and defined polarization, or (b) a number of non-overlapping areas of high intensity with designed shape and relative intensity and designed polarizations, or (c) a number of non-overlapping areas of high intensity with designed shape, relative intensity and polarization that enclose regions with low or no intensity.

39. The apparatus of claim 1, wherein said apparatus is configured for 3D sensing applications.

40. The apparatus of claim 1, wherein said top side high contrast grating (HCG) is configured to operate as: (a) as optical element shaping the characteristics of the emitted far field of the array, or (b) as polarization, angle, mode or wavelength selective mirror of the cavity, or (c) as optical coupler between multiple elements of the array, or (d) as any combination of the above.

41. The apparatus of claim 1:
wherein the at least one said vertical cavity surface emitting laser (VCSEL) comprises a VCSEL array over which said top side high contrast gratings (HCGs) are integrated; and
wherein said apparatus is configured to provide beam steering and polarization switching by electrically addressing either individually, and/or in groups, the VCSELs within the VCSEL.

42. A vertical cavity surface emitting laser (VCSEL) apparatus, comprising:
(a) a vertical cavity surface emitting laser (VCSEL) array in which each VCSEL comprises:
(i) a lower electrode;
(ii) a lower distributed Bragg reflector (DBR) associated with said lower electrode;
(iii) a quantum well structure over said lower DBR;
(iv) an upper reflector over said quantum well structure;
(v) an upper electrode; and
(b) at least one high contrast grating integrated over the top side surface of said VCSEL array, or its individual VCSELs, as a top side high contrast grating which is configured as an optically active structure for modifying emissions of said at least one VCSEL to enable optical functionalities; and
(c) wherein said top side high contrast gratings (HCGs) are integrated to control far field patterns of the elements of the array to provide far field control of portions of the VCSEL array or the whole VCSEL array.

43. A method of extending functionalities of a vertical cavity surface emitting laser (VCSEL), comprising:
(a) fabricating at least one vertical cavity surface emitting laser (VCSEL) having a lower electrode, lower distributed Bragg reflector (DBR), a quantum well structure, an upper reflector over said quantum well structure, a planar top side surface over the VCSEL, and an upper electrode; and
(b) integrating a high contrast grating into the planar top side surface of said VCSEL as a top side high contrast grating which is configured as an optically active structure for modifying emissions of said at least one VCSEL to enable optical functionalities.
